(19) United States
(12) Patent Application Publication
(10) Pub. No.: US 2025/0391600 A1
(43) Pub. Date: Dec. 25, 2025

(54) INDUCTOR, BOARD MODULE, AND METHOD FOR MANUFACTURING INDUCTOR

(71) Applicant: Panasonic Intellectual Property Management Co., Ltd., Osaka (JP)

(72) Inventors: Kiyoshi TAKAGI, Hyogo (JP); Yusuke NAKAMURA, Hyogo (JP); Masahiro ENOMOTO, Osaka (JP); Hiroshi TOMITA, Nara (JP)

(73) Assignee: Panasonic Intellectual Property Management Co., Ltd., Osaka (JP)

(21) Appl. No.: 19/103,766

(22) PCT Filed: May 25, 2023
(86) PCT No.: PCT/JP2023/019583

§ 371 Date: Feb. 13, 2025

(30) Foreign Application Priority Data
Aug. 25, 2022 (JP) 2022-134494

(51) Int. Cl. H01F 27/29; H01F 27/24; H01F 41/02; H01F 41/04; H05K 1/18

(52) U.S. Cl. CPC H01F 27/292; H01F 27/24; H01F 41/0206; H01F 41/04; H05K 1/181; H05K 2201/1003

(57) ABSTRACT

An inductor includes: a magnetic core; a coil portion; and a first electrode and a second electrode. The magnetic core includes a bottom surface, a top surface, a first side surface, a second side surface, a third side surface, and a fourth side surface. The coil portion is arranged with a coil axis intersecting the first side surface and including one end and an other end respectively located at both ends of a conductive path of the coil portion. One end and the other end are in contact with the third side surface and are spaced apart from each other on the third side surface. The first electrode is connected to the one end at the third side surface and is arranged along the third side surface. The second electrode is connected to the other end at the third side surface and is arranged along the third side surface.

### TECHNICAL FIELD

The present disclosure relates to an inductor, a board module including the inductor, and a method for manufacturing the inductor.

### BACKGROUND ART

Inductors, which are passive elements that store electric energy as magnetic energy, are used in, for example, DC-DC converters for the purpose of smoothing step-up/step-down power supply voltage and direct current. An inductor is provided on the surface of a printed circuit board, for example.

Patent Literature (PTL) 1 discloses an inductor including a core main body, a coil element wound around the core main body, and two core members disposed at both ends of the coil element.

### CITATION LIST

### Patent Literature

### [PTL 1] Japanese Unexamined Patent Application Publication No. 2019-129253

### SUMMARY OF INVENTION

### Technical Problem

It is desired to improve mounting efficiency of inductors on printed circuit boards. The present disclosure provides an inductor and so on that can improve the mounting efficiency.

### Solution to Problem

An inductor according to one aspect of the present disclosure includes: a magnetic core including a magnetic material; a coil portion provided inside the magnetic core; and a first electrode and a second electrode that are arranged outside the magnetic core. The magnetic core has a rectangular parallelepiped shape and includes a bottom surface, a top surface opposite to the bottom surface, a first side surface connecting the bottom surface and the top surface, a second side surface opposite to the first side surface, a third side surface perpendicular to the bottom surface and the top surface and connecting the bottom surface and the top surface, and a fourth side surface opposite to the third side surface, the coil portion is arranged with a coil axis intersecting the first side surface and includes one end and an other end respectively located at both ends of a conductive path of the coil portion, the one end and the other end of the coil portion are in contact with the third side surface and are spaced apart from each other on the third side surface, the first electrode is connected to the one end of the coil portion at the third side surface and is arranged along the third side surface, and the second electrode is connected to the other end of the coil portion at the third side surface and is arranged along the third side surface.

A board module according to one aspect of the present disclosure includes: the inductor described above; an electronic component different from the inductor; and a printed circuit board. The inductor is provided on the printed circuit board, and the electronic component is disposed between the bottom surface of the magnetic core of the inductor and the printed circuit board.

A method for manufacturing an inductor according to one aspect of the present disclosure is a method for manufacturing an inductor that includes: a magnetic core including a magnetic material; a coil portion provided inside the magnetic core; and a first electrode and a second electrode that are connected to the coil portion and arranged outside the magnetic core. The method includes: forming a die-cut conductor plate including regions that become the coil portion, the first electrode, and the second electrode by die-cutting a metal plate; forming the magnetic core having a rectangular parallelepiped shape and including four side surfaces and forming a coil portion with a coil axis intersecting two side surfaces of the magnetic core by covering a portion of the die-cut conductor plate with a magnetic material; and forming the first electrode and the second electrode that protrude from one side surface of other two side surfaces different from the two side surfaces by bending portions of the die-cut conductor plate that are not covered with the magnetic material and arranged outside the magnetic core.

### Advantageous Effects of Invention

The inductor and so on according to the present disclosure can improve the mounting efficiency.

### BRIEF DESCRIPTION OF DRAWINGS

FIG. 1 is a perspective view illustrating an inductor according to an embodiment.

FIG. 2 is a diagram illustrating a coil portion, electrodes, etc. of the inductor according to the embodiment.

FIG. 3 includes a front view, a left side view, a right side view, a top view, and a bottom view of the inductor according to the embodiment.

FIG. 4 is a flowchart illustrating a method for manufacturing the inductor according to the embodiment.

FIG. 5 is a diagram illustrating a metal plate to be used as a material of the coil portion, the electrodes, etc.

FIG. 6 is a diagram illustrating a die-cut conductor plate formed by die-cutting.

FIG. 7 is a diagram illustrating a magnetic core formed by a step of forming a magnetic core and a coil portion.

FIG. 8 is a diagram illustrating a board module including the inductor according to the embodiment.

FIG. 9A is a top view of the inductor, wires, and land electrodes provided on the board module according to the embodiment.

FIG. 9B is a diagram illustrating another example of the board module.

FIG. 10 is a front view of an inductor according to Variation 1 of the embodiment.

FIG. 11 includes a front view, a left side view, and a right side view of an inductor according to Variation 2 of the embodiment.

### DESCRIPTION OF EMBODIMENTS

The following specifically describes one or more embodiments with reference to the drawings. Note that each of the one or more embodiments described below shows a specific example of the present disclosure. The numerical values, shapes, materials, structural elements, the arrangement positions and connection of the structural elements, steps, the processing order of the steps, etc. shown in the following one or more embodiments are mere examples, and are not intended to limit the scope of the present disclosure. In addition, among the structural elements in the following one or more embodiments, structural elements not recited in any one of the independent claims are described as optional structural elements.

In addition, in the present specification, terms indicating relationships between elements, such as “parallel”, terms indicating the shapes of elements, such as “rectangular parallelepiped”, and numerical ranges are not limited to their strict meanings, but also include substantially equivalent ranges, for example, differences of a few percent or several percent.

In addition, each figure is a schematic diagram with emphasis, omission, or ratio adjustment as appropriate to illustrate the present disclosure, and is not necessarily a precise depiction. Each figure may differ from the actual shapes, positional relationships, and ratios. Configurations that are essentially the same share like reference signs in the figures. Accordingly, overlapping explanations thereof may be omitted or simplified.

Moreover, each figure shows an X-axis, a Y-axis, and a Z-axis which mean three directions orthogonal to each other, and these axes and directions along these axes are used for explanation, as necessary. Note that the axes are shown for illustrative purposes only and do not limit the direction and orientation in which an inductor is used.

In addition, in the present specification, the terms “top surface” and “bottom surface” in the configuration of an inductor do not refer to the top surface (vertically upward surface) and the bottom surface (vertically downward surface) in absolute spatial recognition, but are used as terms defined by the relative positional relationship of the structural elements of an inductor.

### Embodiment

### Configuration of Inductor

A configuration of an inductor according to an embodiment will be descried. An inductor is a passive element that stores electrical energy flowing through a coil portion as magnetic energy.

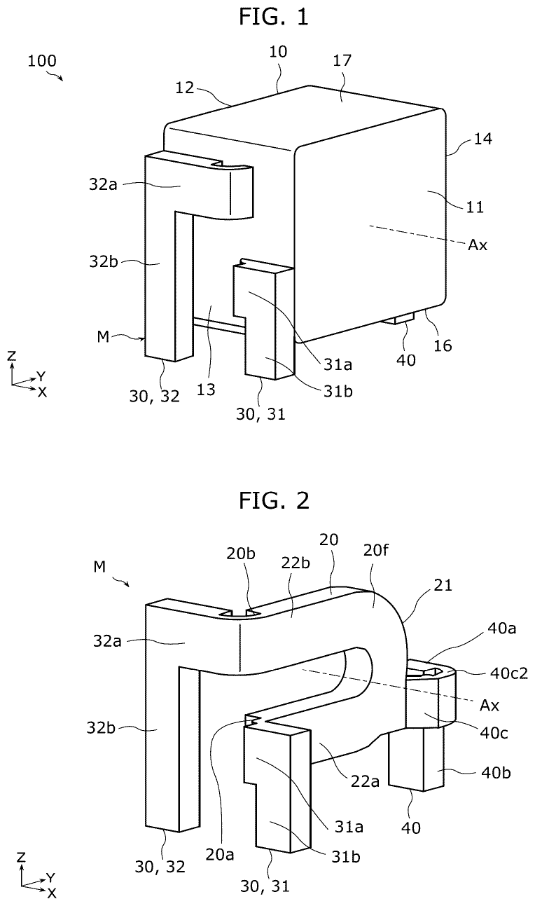

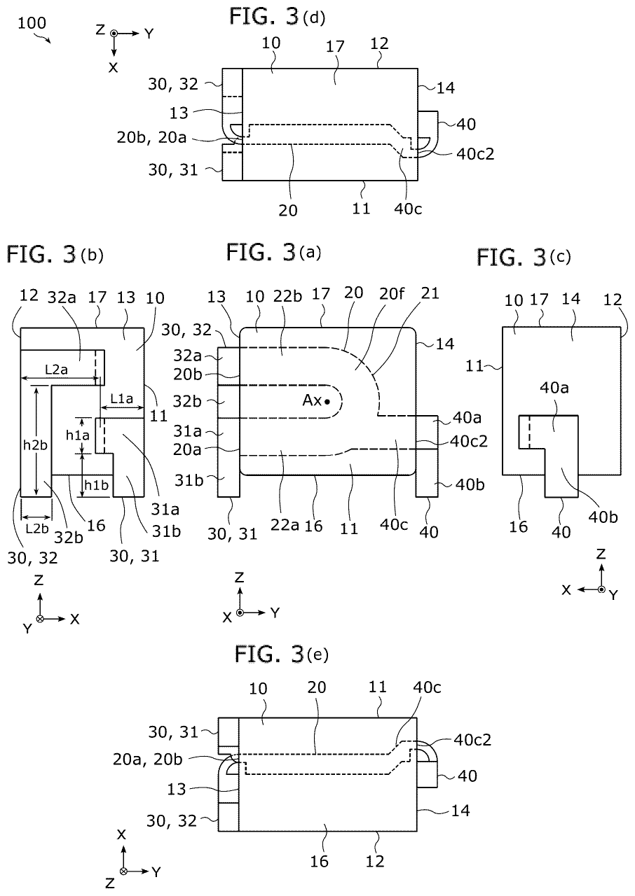

FIG. 1 is a perspective view illustrating inductor 100 according to the embodiment. FIG. 2 is a diagram illustrating coil portion 20, electrodes 30, etc. of inductor 100. FIG. 3 includes a front view, a left side view, a right side view, a top view, and a bottom view of inductor 100 according to the embodiment.

FIG. 2 illustrates a state in which magnetic core 10 is removed from inductor 100 illustrated in FIG. 1. In FIG. 3, (a) is a front view, (b) is a left side view, (c) is a right side view, (d) is a top view, and (e) is a bottom view. Note that the front view of inductor 100 is as viewed in the X-axis direction, the left side view and the right side view of inductor 100 are as viewed in the Y-axis direction, and the top and bottom views of inductor 100 are as viewed in the Z-axis direction.

Inductor 100 illustrated in FIGS. 1 to 3 includes magnetic core 10 including a magnetic material, coil portion 20 provided inside magnetic core 10, and electrodes 30 arranged outside magnetic core 10. In addition, inductor 100 includes support conductor 40 for supporting the orientation of magnetic core 10. As illustrated in FIG. 2, coil portion 20, electrodes 30, and support conductor 40 are formed by portions of metal component M.

For example, the approximate outline of inductor 100 illustrated in FIG. 1 is determined by the shape of magnetic core 10, which is a magnetic molded body having a rectangular parallelepiped shape. Note that magnetic core 10 can be molded into any shape by metal molding. In other words, inductor 100 having any shape can be produced based on the shape of magnetic core 10 at the time of molding. For example, the dimensions of magnetic core 10 are 5.6 mm in the X-axis direction, 9.0 mm in the Y-axis direction, and 6.7 mm in the Z-axis direction.

Magnetic core 10 is the outer shell part of inductor 100 and partially covers metal component M. Magnetic core 10 includes a magnetic material, and is, for example, a dust core including metal magnetic powder, a resin material, etc. Note that magnetic core 10 may be formed using any magnetic materials. As the magnetic material, ferrite may be used, or other magnetic materials may be used. As the metal magnetic powder, a particulate material having a predetermined elemental composition may be used. For example, a Fe—Si—Al based material, a Fe—Si based material, a Fe—Si—Cr based material, or a Fe—Si—Cr—B based material may be used. Moreover, as the resin material, a material, such as a silicone-based resin, that can maintain a certain shape by bonding the metal magnetic powder together while insulating the particles of the metal magnetic powder is selected.

As illustrated in FIGS. 1 and 3, magnetic core 10 has, for example, a rectangular parallelepiped shape. Magnetic core 10 includes bottom surface 16, top surface 17 opposite to bottom surface 16, and four side surfaces 11, 12, 13, and 14 connecting bottom surface 16 and top surface 17. The four side surfaces are made up of first side surface 11, second side surface 12, third side surface 13, and fourth side surface 14. Outer peripheral side surfaces of magnetic core 10 in the figures are formed by four side surfaces 11 to 14.

First side surface 11 and second side surface 12 are aligned in the X axis direction and opposite to each other. Third side surface 13 and fourth side surface 14 are aligned in the Y axis direction and opposite to each other. Bottom surface 16 and top surface 17 are aligned in the Z-axis direction and opposite to each other. Each of bottom surface 16, top surface 17, and four side surfaces 11 to 14 is substantially a flat surface. Bottom surface 16 of magnetic core 10 has a rectangular shape. First side surface 11 and second side surface 12 are connected to the long sides of bottom surface 16, and third side surface 13 and fourth side surface 14 are connected to the short sides of bottom surface 16.

The pair of bottom side surface 16 and top surface 17, the pair of first side surface 11 and second side surface 12, and the pair of third side surface 13 and fourth side surface 14 are pairs of surfaces with parallel positional relationships. Each of side surfaces 11 to 14 has a perpendicular positional relationship with bottom surface 16 and top surface 17. Each of first side surface 11 and second side surface 12 has a perpendicular positional relationship with third side surface 13 and fourth side surface 14. Each corner portion (edge portion) where surfaces of magnetic core 10 intersect may have a roundness.

Metal component M illustrated in FIGS. 1 and 2 includes coil portion 20 located inside magnetic core 10, electrodes 30 located outside magnetic core 10, and support conductor 40 located inside and outside magnetic core 10.

Metal component M is formed by, for example, die-cutting a metal plate having a thickness of 1 mm and then bending the metal plate. Metal component M includes, for example, a metallic material selected from a metal such as aluminum, copper, silver, and gold; an alloy including one or more of these metals; and a material including a metal or an alloy and another material. Coil portion 20, electrodes 30, and support conductor 40 are names given to each portion formed by processing one component including the same material.

Coil portion 20 is a portion covered by magnetic core 10. Coil portion 20 is arranged with coil axis Ax of coil portion 20 intersecting first side surface 11 and second side surface 12. Specifically, coil portion 20 is arranged with coil axis Ax being perpendicular to first side surface 11 and second side surface 12.

Coil portion 20 has a planar shape and flat surface 20f of coil portion 20 is perpendicular to bottom surface 16. Flat surface 20f of coil portion 20 is a coil surface of the planar coil perpendicular to coil axis Ax. Moreover, coil portion 20 may be arranged closer to first side surface 11 than to second side surface 12 when viewed from a side on which top surface 17 is located. In other words, coil portion 20 is located toward first side surface 11 from the middle line between first side surface 11 and second side surface 12 when viewed from the side on which top surface 17 is located.

Coil portion 20 includes coil main body 21 and two coil lead portions 22a and 22b respectively connected to both ends of coil main body 21.

Coil main body 21 is an arcuate and strip-shaped plate and having the number of turns of 0.5 turns. The shape of coil main body 21 is not limited to the arcuate, but may be C-shaped, U-shaped or V-shaped. The cross-section of coil main body 21 is rectangular, and for example, each long side is 2.5 mm in length and each short side is 1.0 mm in length. Coil main body 21 is wound such that the short sides are parallel to coil axis Ax. The shape, the number of turns, and coil length of coil main body 21 are not particularly limited and may be appropriately selected according to constraints such as the performance required for inductor 100 and the size of magnetic core 10.

The two coil lead portions 22a and 22b are portions that respectively connect to both ends of coil main body 21. One coil lead portion 22a of the two coil lead portions 22a and 22b is led out linearly toward third side surface 13 from the end of coil main body 21 that is closer to bottom surface 16, and the other coil lead portion 22b is led out linearly toward third side surface 13 from the end of coil main body 21 that is closer to top surface 17.

Coil portion 20 includes one end 20a and other end 20b respectively located at both ends of the conductive path of coil portion 20. One end 20a of coil portion 20 is located at the leading end of one coil lead portion 22a and other end 20b of coil portion 20 is located at the leading end of the other coil lead portion 22b.

One end 20a and other end 20b of coil portion 20 are in contact with third side surface 13 and are spaced apart from each other on third side surface 13. One end 20a of coil portion 20 is arranged closer to bottom surface 16 than other end 20b is. In other words, other end 20b of coil portion 20 is arranged closer to top surface 17 than one end 20a is. One end 20a and other end 20b are arranged at the same distance from first side surface 11. In other words, one end 20a and other end 20b are arranged on the same axis line in the the Z axis direction, as viewed in the direction perpendicular to third side surface 13.

Electrodes 30 are portions where inductor 100 is connected to the wiring pattern, etc. on the printed circuit board when inductor 100 is provided on the printed circuit board. Electrodes 30 include first electrode 31 and second electrode 32.

First electrode 31 and second electrode 32, illustrated in FIGS. 1 and 3, protrude from third side surface 13, which is one of the four side surfaces. First electrode 31 is connected to one end 20a of coil portion 20 at third side surface 13 and is arranged along third side surface 13. Second electrode 32 is connected to other end 20b of coil portion 20 at third side surface 13 and is arranged along third side surface 13. As viewed in the direction perpendicular to third side surface 13, first electrode 31 is located between one end 20a of coil portion 20 and first side surface 11, and second electrode 32 is located between other end 20b of coil portion 20 and second side surface 12.

First electrode 31 has a plate shape, and includes first lead portion 31a connecting to one end 20a of coil portion 20 and first leg portion 31b connecting to first lead portion 31a.

First lead portion 31a is bent starting at one end 20a of coil portion 20 toward first side surface 11 and extends linearly along third side surface 13 in a direction toward first side surface 11 from one end 20a. Specifically, first lead portion 31a is parallel to the direction perpendicular to first side surface 11 and extends from one end 20a of coil portion 20 to the same plane as first side surface 11. Note that the region that is bent starting at one end 20a of first lead portion 31a is thinner than a linear region of first lead portion 31a. The linear region is a region excluding the region bent starting at one end 20a.

First leg portion 31b is located closer to a side of first lead portion 31a that is closer to bottom surface 16 as viewed from first lead portion 31a. First leg portion 31b is connected to a portion of a face of first lead portion 31a that is closer to bottom surface 16 and extends linearly to at least the same plane as bottom surface 16. First leg portion 31b in the present embodiment protrudes beyond bottom surface 16, to a side opposite to a side on which top surface 17 is located in the Z-axis direction.

Second electrode 32 has a plate shape, and includes second lead portion 32a connecting to other end 20b of coil portion 20, and second leg portion 32b connecting to second lead portion 32a.

Second lead portion 32a is bent starting at other end 20b of coil portion 20 toward second side surface 12 and extends linearly along third side surface 13 in a direction toward second side surface 12 from other end 20b. Specifically, second lead portion 32a is parallel to the direction perpendicular to first side surface 11 and extends from other end 20b of coil portion 20 to the same plane as second side surface 12. That is, second lead portion 32a is bent in the opposite direction to first lead portion 31a and extends in the opposite direction to first lead portion 31a. Note that the region that is bent starting at other end 20b of second lead portion 32a is thinner than a linear region of second lead portion 32a. The linear region is a region excluding the region bent starting at other end 20b.

Second leg portion 32b is located closer to a side of second lead portion 32a that is closer to bottom surface 16 as viewed from second lead portion 32a. Second leg portion 32b is connected to a portion of a face of second lead portion 32a that is closer to bottom surface 16 and extends linearly to at least the same plane as bottom surface 16. Second leg portion 32b in the present embodiment protrudes beyond bottom surface 16, to the side opposite to the side on which top surface 17 is located in the Z-axis direction.

Support conductor 40 is a portion for supporting the orientation of magnetic core 10, and has a portion that protrudes outward from fourth side surface 14. Support conductor 40 includes embedded portion 40c embedded in magnetic core 10, support lead portion 40a connecting to embedded portion 40c, and support leg portion 40b connecting to support lead portion 40a.

One end of embedded portion 40c is connected to a portion of coil portion 20, and another end 40c2 of embedded portion 40c is in contact with fourth side surface 14.

Support lead portion 40a is connected to another end 40c2 of embedded portion 40c at fourth side surface 14. Support lead portion 40a is bent starting at another end 40c2 of embedded portion 40c toward second side surface 12 and extends linearly along fourth side surface 14 in a direction toward second side surface 12. Specifically, support lead portion 40a is parallel to the direction perpendicular to first side surface 11 and extends to a middle position between first side surface 11 and second side surface 12. Note that the region that is bent starting at another end 40c2 of support lead portion 40a is thinner than the linear region of support lead portion 40a. The linear region is a region excluding the region bent starting at another end 40c2.

Support leg portion 40b is located closer to a side of support lead portion 40a that is closer to bottom surface 16 as viewed from support lead portion 40a. Support leg portion 40b is connected to a portion of a face of support lead portion 40a that is closer to bottom surface 16 and extends linearly to at least the same plane as bottom surface 16. Support leg portion 40b in the present embodiment protrudes beyond bottom surface 16, to the side opposite to the side on which top surface 17 is located in the Z-axis direction.

As described above, first leg portion 31b, second leg portion 32b and support leg portion 40b protrude below bottom surface 16. The protrusion lengths of first leg portion 31b, second leg portion 32b and support leg portion 40b are the same. On the regions of first leg portion 31b, second leg portion 32b, and support leg portion 40b protruding beyond bottom surface 16, for example, solder plating is formed (not illustrated).

Moreover, in the present embodiment, the length of the conductive path of second electrode 32 is longer than the length of the conductive path of first electrode 31. As illustrated in (b) in FIG. 3, in the direction perpendicular to first side surface 11 (X-axis direction), length L2a of second lead portion 32a is longer than length L1a of first lead portion 31a. Moreover, in the direction perpendicular to bottom surface 16 (Z-axis direction), length h2b of second leg portion 32b is longer than length h1b of first leg portion 31b.

More specifically, in the direction perpendicular to first side surface 11, the length obtained by subtracting length L2b of second leg portion 32b from length L2a of second lead portion 32a is longer than length L1a of first lead portion 31a ((L2a−L2b)>L1a). Moreover, in the direction perpendicular to bottom surface 16, length h2b of the second leg portion is longer than the sum of length h1b of first leg portion 31b and length h1a of first lead portion 31a (h2b>(h1b +h1a)).

Note that length L1a of first lead portion 31a is a distance from the point connected to one end 20a of coil portion 20 to the point closest to a side on which first side surface 11 is located among the points connected to first leg portion 31b. Length L2a of second lead portion 32a is a distance from the point connected to other end 20b of coil portion 20 to the point closest to a side on which second side surface 12 is located among the points connected to second leg portion 32b. Length L2b of second leg portion 32b is the length of second leg portion 32b in the direction perpendicular to first side surface 11. Moreover, length h1b of first leg portion 31b is a distance from the point connected to first lead portion 31a to the point furthest from first lead portion 31a. Length h2b of second leg portion 32b is a distance from the point connected to second lead portion 32a to the point furthest from second lead portion 32a. Length h1a of first leg portion 31b is the length of first leg portion 31b in the direction perpendicular to bottom surface 16.

In the present embodiment, coil portion 20 of inductor 100 is arranged with coil axis Ax of coil portion 20 intersecting first side surface 11. With this configuration, the coil surface perpendicular to coil axis Ax can be positioned upright, and the surface area of bottom surface 16 of magnetic core 10 can be reduced compared to the case where the coil surface is positioned parallel to bottom surface 16. This makes it possible to improve the mounting efficiency of inductor 100. Moreover, in the present embodiment, first electrode 31 and second electrode 32 are respectively connected to one end 20a and other end 20b of coil portion 20 at third side surface 13 and are arranged along third side surface 13. With this configuration, two electrodes 30 are arranged on one side surface of magnetic core 10, and the input and output terminals of inductor 100 can be concentrated on one side surface of magnetic core 10. This makes it possible to improve the mounting efficiency of inductor 100.

### Method for Manufacturing Inductor

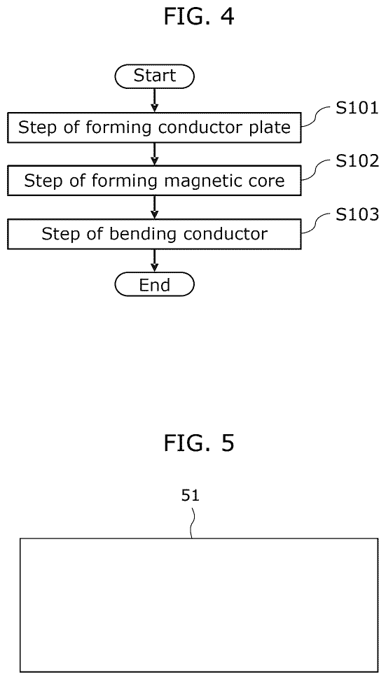

Next, a method for manufacturing the aforementioned inductor 100 will be described with reference to FIGS. 4 to 7 as appropriate.

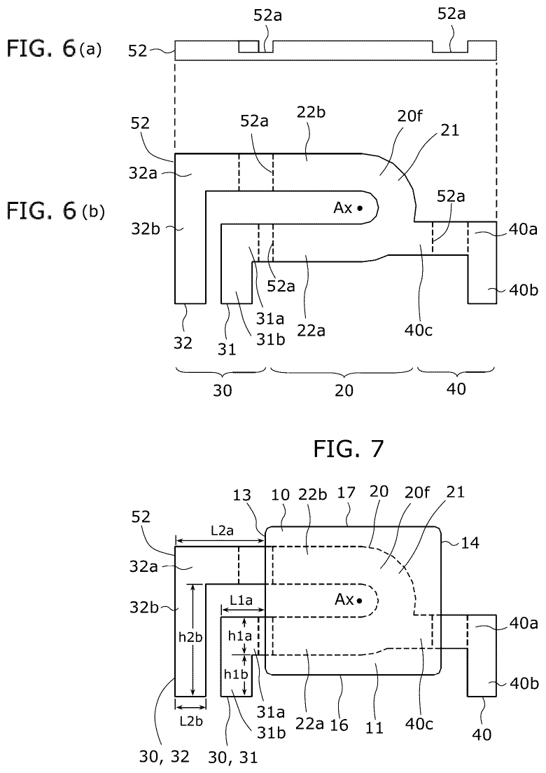

FIG. 4 is a flowchart illustrating a method for manufacturing inductor 100 according to the embodiment. FIG. 5 is a diagram illustrating metal plate 51 to be used as a material of coil portion 20, electrodes 30, etc. FIG. 6 is a diagram illustrating die-cut conductor plate 52 formed by die-cutting. FIG. 7 is a diagram illustrating magnetic core 10 formed by a step of forming a magnetic core and coil portion 20. In FIG. 6, (b) is a front view, and (a) is a top view of (b).

As illustrated in FIG. 4, the method for manufacturing inductor 100 includes step S101 of forming a conductor plate, step S102 of forming a magnetic core, step S103 of bending the conductor.

In step S101 of forming a conductor plate, metal plate 51 illustrated in FIG. 5 is die-cut into a predetermined shape to form die-cut conductor plate 52 illustrated FIG. 6. Specifically, die-cutting metal plate 51 having a thickness of 1 mm by press molding to form a region that becomes coil portion 20, regions that becomes electrodes 30, and a region that becomes support conductor 40.

The region that becomes coil portion 20 has a shape which is a U-shape rotated 90° to the left. The regions that become electrodes 30 are connected to both ends of coil portion 20 that are located on the left side of the region that becomes coil portion 20. In this example, the region that becomes first electrode 31 is connected to one coil lead portion 22a of coil portion 20, and the region that becomes second electrode 32 is connected to the other coil lead portion 22b of coil portion 20.

The region that becomes second lead portion 32a of second electrode 32 is formed above the area that becomes first lead portion 31a of first electrode 31 (in the opposite direction to first leg portion 31b as seen from first lead portion 31a). The region that becomes second leg portion 32b of second electrode 32 is formed on the left side of the region that becomes first leg portion 31b of first electrode 31 (in the opposite direction to coil portion 20 as viewed from first leg portion 31b). The region that becomes support conductor 40 is connected to the region that becomes coil portion 20. The region that becomes support conductor 40 is formed on the right side of the region that becomes coil portion 20 (in the opposite direction to the region that becomes electrodes 30 as viewed from the region that becomes coil portion 20). In this way, the regions that become coil portion 20, electrodes 30, and support conductor 40 are connected as one conductor plate. In step S101 of forming a conductor plate, the regions that become coil portion 20, electrodes 30, and support conductor 40 are formed by a single die-cutting operation.

Moreover, in step S101 of forming a conductive plate, a plurality of recesses 52a illustrated in FIG. 6 are formed in the region to be bent in the bending in the subsequent step. Recesses 52a are formed by pressing a U-shaped tool against die-cut conductor plate 52, for example. In this example, by pressing the back side of die-cut conductor plate 52, recesses 52a are formed in the thickness direction of die-cut conductor plate 52. The depth of each recess 52a is, for example, at least 0.5 mm and at most 0.7 mm. Recesses 52a may be provided after the die-cutting or may be formed before the die-cutting. Recesses 52a may be formed by cutting or etching.

In step S102 of forming a magnetic core, magnetic core 10 is press-molded together with die-cut conductor plate 52 (see FIG. 7). In this step, a portion of die-cut conductor plate 52 is placed in a mold such that the portion of die-cut conductor plate 52 is covered with a mixture containing magnetic material powder and a binder and the other portions of die-cut conductor plate 52 are not covered with the magnetic material powder and the binder. Then, press molding is performed to form magnetic core 10. The portion of die-cut conductor plate 52 covered by magnetic core 10 becomes coil portion 20, and the other portions of die-cut conductor plate 52 that are not covered by magnetic core 10 become electrodes 30 and support conductor 40. The pressure to be applied in the compression molding is, for example, 5 tons/cm², and the thermosetting temperature is, for example, 185° C.

After step S102 of forming a magnetic core, electrodes 30, which are not covered by magnetic core 10, protrude perpendicularly outward from third side surface 13 of magnetic core 10. The portion of support conductor 40, which is not covered by magnetic core 10, protrudes perpendicularly outward from fourth side surface 14 of magnetic core 10. The length obtained by subtracting length L2b of second leg portion 32b from length L2a of second lead portion 32a is longer than length L1a of first lead portion 31a ((L2a−L2b)>L1a). Moreover, length h2b of the second leg portion is longer than the sum of length h1b of first leg portion 31b and length h1a of first lead portion 31a (h2b>(h1b+h1a)).

In step S103 of bending the conductor, electrodes 30 protruding from magnetic core 10 and support conductor 40 are bent. First electrode 31 is bent starting at one end 20a of coil portion 20 along third side surface 13 toward first side surface 11. Second electrode 32 is bent starting at other end 20b of coil portion 20 along third side surface 13 toward second side surface 12. Support conductor 40 is bent starting at another end 40c2 of embedded portion 40c along fourth side surface 14 toward second side surface 12. First electrode 31 and second electrode 32 may be bent at the same time. Alternatively, second electrode 32 and support conductor 40 may be bent at the same time.

After step S103 of bending the conductor, for example, solder plating is applied to the regions of first electrode 31, second electrode 32 and support conductor 40 protruding below bottom surface 16. These steps produce inductor 100.

### Board Module

Board module 60 including inductor 100 according to the embodiment will be described.

FIG. 8 is a diagram illustrating board module 60 including inductor 100 according to the embodiment.

As illustrated in FIG. 8, board module 60 includes inductor 100, electronic component 69 different from inductor 100, and printed circuit board 61. Note that in FIG. 8, illustration of wires, land electrodes, and bonding agents such as solder on printed circuit board 61 is omitted.

Printed circuit board 61 is a board provided inside electrical equipment, etc. Printed circuit board 61 includes a plurality of electronic components 69.

Electronic components 69 are surface-mounted electronic components, such as a capacitor, a resistor, a transistor, etc. Electronic components 69 are mounted on printed circuit board 61 with solder, etc.

As described above, first electrode 31, second electrode 32, and support conductor 40 of inductor 100 protrudes below bottom surface 16, and inductor 100 is provided on printed circuit board 61 to cover electronic components 69 on printed circuit board 61. Inductor 100 is provided on printed circuit board 61 such that the bottom surfaces of first electrode 31, second electrode 32, and support conductor 40 abut or are adjacent to mounting surface 61a of printed circuit board 61, and is joined by a bonding agent such as solder (not illustrated).

In this board module 60, first electrode 31, second electrode 32, and support conductor 40 protrude below bottom surface 16, and thus a space is formed between bottom surface 16 of magnetic core 10 and mounting surface 61a of printed circuit board 61. Electronic components 69 are disposed between bottom surface 16 of magnetic core 10 of inductor 100 and printed circuit board 61. With this configuration, the mounting density of board module 60 can be increased.

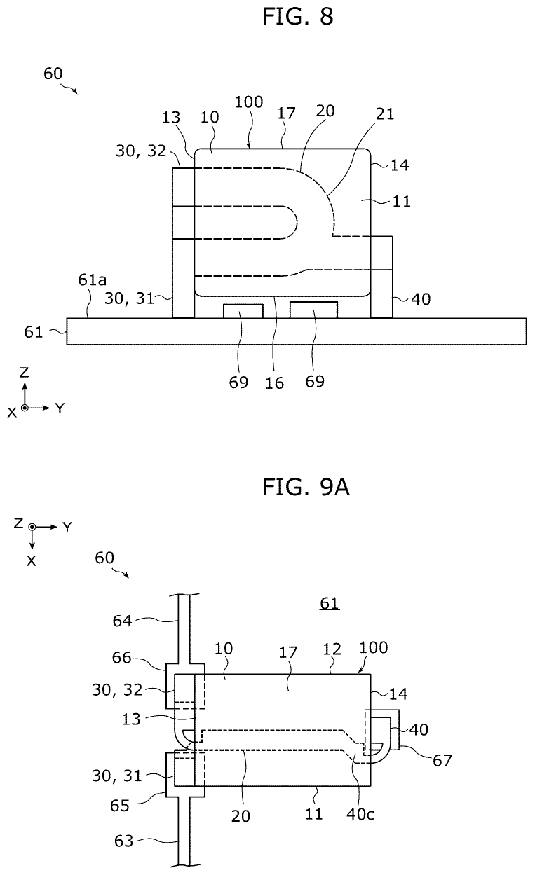

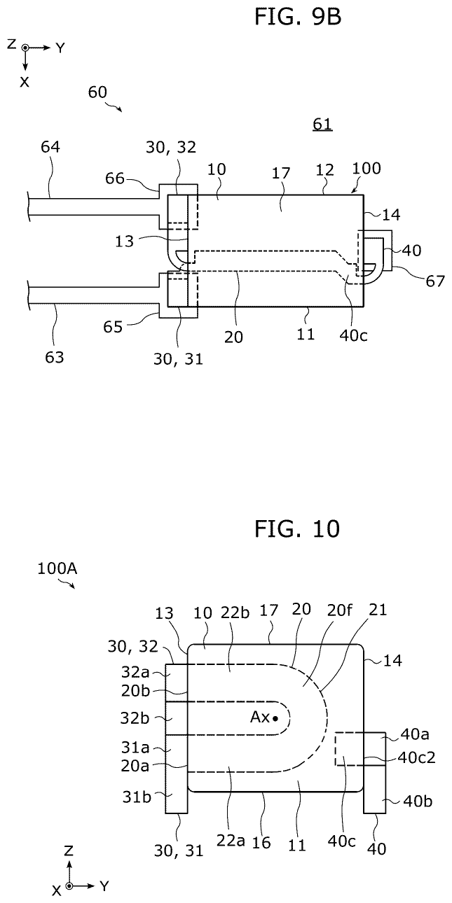

FIG. 9A is a top view of inductor 100, wires 63 and 64, and land electrodes 65, 66, and 67 provided on board module 60. FIG. 9B is a diagram illustrating another example of printed circuit module 60. Note that FIGS. 9A and 9B omit illustration of bonding agents such as solder.

FIG. 9A illustrates an example in which wires 63 and 64 are formed parallel to third side surface 13 of inductor 100. FIG. 9B illustrates an example in which wires 63 and 64 are formed perpendicular to third side surface 13 of inductor 100.

First electrode 31 of inductor 100 is connected to wire 63 via land electrode 65, and second electrode 32 is connected to wire 64 via land electrode 66. In board module 60, power from power supply or an electrical signal is input and output to first electrode 31 and second electrode 32 via wires 63 and 64 and land electrodes 65 and 66.

On the other hand, support conductor 40 of inductor 100 is joined to land electrode 67, but no wire is connected to land electrode 67, and power from power supply or electrical signal is not input to support conductor 40 via land electrode 67. In other words, board module 60 illustrated in FIGS. 9A and 9B does not require routing wiring for land electrode 67 arranged on a side on which fourth side surface 14 is located.

This board module 60 makes it possible to provide wires 63 and 64 on a side on which third side surface 13 of inductor 100 is located. This makes it possible to improve the wiring efficiency of board module 60.

### Variation 1 of Embodiment

Inductor 100A according to Variation 1 of the embodiment will be described. Variation 1 describes an example in which support conductor 40 is not connected to coil portion 20.

FIG. 10 illustrates a front view of inductor 100A according to Variation 1 of the embodiment.

Inductor 100A illustrated in FIG. 10 includes magnetic core 10, coil portion 20, and electrodes 30. Moreover, inductor 100A includes support conductor 40 for supporting the orientation of magnetic core 10. The respective configurations of magnetic core 10, coil portion 20, and electrodes 30 are the same as the configurations in the embodiment.

Support conductor 40 includes embedded portion 40c embedded in magnetic core 10, support lead portion 40a connecting to embedded portion 40c, and support leg portion 40b connecting to support lead portion 40a.

Support conductor 40 in Variation 1 is formed by a metal component different from metal component M forming coil portion 20 and electrodes 30. As illustrated in FIG. 10, one end of embedded portion 40c in Variation 1 is not connected to coil portion 20, but is embedded in magnetic core 10. This means that support conductor 40 is not connected to coil portion 20 and is electrically floating in inductor 100A. Inductor 100A of Variation 1 also has the same effects as in the embodiment.

### Variation 2 of Embodiment

Inductor 100B according to Variation 2 of the embodiment will be described. In Variation 2, an example in which first electrode 31, second electrode 32, and support conductor 40 do not protrude below bottom surface 16, and are flush with bottom surface 16 will be described.

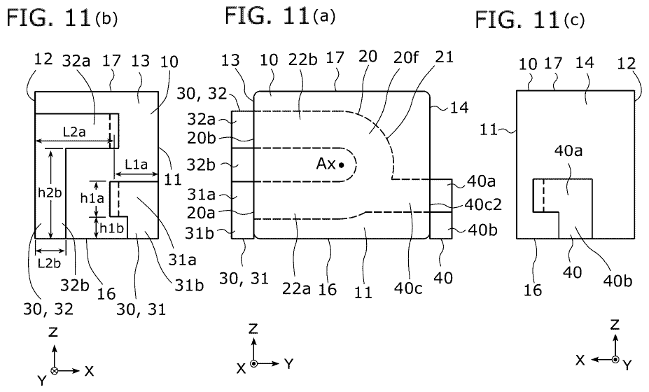

FIG. 11 includes a front view, a left side view, and a right side view of inductor 100B according to Variation 2 of the embodiment. In FIG. 11, (a) is a front view, (b) is a left side view, and (c) is a right side view.

Inductor 100B illustrated in FIG. 11 includes magnetic core 10, coil portion 20, and electrodes 30. Moreover, inductor 100B includes support conductor 40 for supporting the orientation of magnetic core 10. The respective configurations of magnetic core 10 and coil portion 20 are the same as the configurations in the embodiment.

In inductor 100B according to Variation 2, first electrode 31, second electrode 32, and support conductor 40 are on the same plane as bottom surface 16, and do not protrude below bottom surface 16. Therefore, it is not possible to arrange other electronic components 69 between bottom surface 16 of magnetic core 10 and printed circuit board 61 as in the embodiment.

However, also in Variation 2, coil portion 20 of inductor 100B is arranged with coil axis Ax intersecting first side surface 11. With this configuration, the coil surface perpendicular to coil axis Ax can be positioned upright, and the surface area of bottom surface 16 of magnetic core 10 can be reduced. This makes it possible to improve the mounting efficiency of inductor 100B. Moreover, in Variation 2, first electrode 31 and second electrode 32 are respectively connected to one end 20a and other end 20b of coil portion 20 at third side surface 13, and are arranged along third side surface 13. With this configuration, two electrodes 30 are arranged on one side surface of magnetic core 10, and the input and output terminals of inductor 100B can be concentrated on one side surface of magnetic core 10. This makes it possible to improve the mounting efficiency of inductor 100B.

Note that, in Variation 2, an example of inductor 100B including support conductor 40 has been described, but inductor 100B does not necessarily include support conductor 40. For example, when magnetic core 10 and electrodes 30 are mounted on printed circuit board 61 via conductive adhesive, inductor 100B in Variation 2 can stabilize the orientation of magnetic core 10 by the conductive adhesive even without support conductor 40.

### Conclusion

As described above, inductor 100 according to the present embodiment includes: magnetic core 10 including a magnetic material; coil portion 20 provided inside magnetic core 10; and first electrode 31 and second electrode 32 that are arranged outside magnetic core 10. Magnetic core 10 has a rectangular parallelepiped shape and includes bottom surface 16, top surface 17 opposite to bottom surface 16, first side surface 11 connecting bottom surface 16 and top surface 17, second side surface 12 opposite to first side surface 11, third side surface 13 connecting bottom surface 16 and top surface 17, and fourth side surface 14 opposite to third side surface 13. Coil portion 20 is arranged with coil axis Ax intersecting first side surface 11 and includes one end 20a and other end 20b respectively located at both ends of a conductive path of coil portion 20. One end 20a and other end 20b of coil portion 20 are in contact with third side surface 13 and are spaced apart from each other on third side surface 13. First electrode 31 is connected to one end 20a of coil portion 20 at third side surface 13 and is arranged along third side surface 13. Second electrode 32 is connected to other end 20b of coil portion 20 at third side surface 13 and is arranged along third side surface 13.

As described above, coil portion 20 of inductor 100 is arranged with coil axis Ax intersecting first side surface 11. With this configuration, the coil surface perpendicular to coil axis Ax can be positioned upright, and the surface area of bottom surface 16 of magnetic core 10 can be reduced. This makes it possible to improve the mounting efficiency of inductor 100. Moreover, in inductor 100, first electrode 31 and second electrode 32 are respectively connected to one end 20a and other end 20b of coil portion 20 at third side surface 13, and are arranged along third side surface 13. With this configuration, two electrodes can be arranged on one side surface of magnetic core 10, and the input and output terminals of inductor 100 can be concentrated on one side surface of magnetic core 10. This makes it possible to improve the mounting efficiency of inductor 100.

Moreover, coil portion 20 has a plate shape, and flat surface 20f of coil portion 20 may be perpendicular to bottom surface 16.

Accordingly, since flat surface 20f of coil portion 20 is perpendicular to bottom surface 16, the surface area of bottom surface 16 of magnetic core 10 can be reduced compared with the case where flat surface 20f of coil portion 20 is positioned parallel to bottom surface 16. This makes it possible to improve the mounting efficiency of inductor 100.

Moreover, other end 20b of coil portion 20 may be arranged closer to top surface 17 than one end 20a of coil portion 20 is. As viewed in a direction perpendicular to third side surface 13, first electrode 31 is arranged between one end 20a of coil portion 20 and first side surface 11, and second electrode 32 is arranged between other end 20b of coil portion 20 and second side surface 12.

With this configuration, first electrode 31 and second electrode 32 can be arranged on one side surface of magnetic core 10, and the input and output terminals of inductor 100 can be concentrated on one side surface of magnetic core 10. This makes it possible to improve the mounting efficiency of inductor 100.

Moreover, first electrode 31 may include first lead portion 31a that extends in a direction toward first side surface 11 from one end 20a of coil portion 20, and first leg portion 31b that is connected to first lead portion 31a and extends to at least a same plane as bottom surface 16. Second electrode 32 includes second lead portion 32a that extends in a direction toward second side surface 12 from other end 20b of coil portion 20, and second leg portion 32b that is connected to second lead portion 32a and extends to at least a same plane as bottom surface 16.

With this configuration, first electrode 31 and second electrode 32 can be appropriately arranged on one side surface of magnetic core 10, and the input and output terminals of inductor 100 can be concentrated on one side surface of magnetic core 10. This makes it possible to improve the mounting efficiency of inductor 100.

Moreover, in a direction perpendicular to first side surface 11, length L2a of second lead portion 32a may be longer than a length L1a of first lead portion 31a.

With this configuration, first electrode 31 and second electrode 32 can be appropriately arranged on one side surface of magnetic core 10, and the input and output terminals of inductor 100 can be concentrated on one side surface of magnetic core 10. This makes it possible to improve the mounting efficiency of inductor 100. In addition, with this configuration, the regions that become first electrode 31 and second electrode 32 can be formed at the same time by die-cutting, for example. This makes it possible to improve the production efficiency of inductor 100.

Moreover, in a direction perpendicular to bottom surface 16, length h2b of second leg portion 32b may be longer than length h1b of first leg portion 31b.

With this configuration, first electrode 31 and second electrode 32 are arranged on one side surface of magnetic core 10 without being in contact with each other, and the input and output terminals of inductor 100 can be concentrated on one side surface of magnetic core 10. This makes it possible to improve the mounting efficiency of inductor 100. Moreover, with this configuration, the regions that become first electrode 31 and second electrode 32 can be formed at the same time by die-cutting, for example. This makes it possible to improve the production efficiency of inductor 100.

Moreover, each of first electrode 31 and second electrode 32 has a plate shape. First leg portion 31b is connected to a face of first lead portion 31a that is closer to bottom surface 16, and second leg portion 32b is connected to a face of second lead portion 32a that is closer to bottom surface 16. In a direction perpendicular to first side surface 11, a length obtained by subtracting length L2b of second leg portion 32b from length L2a of second lead portion 32a is longer than length L1a of first lead portion 31a. In a direction perpendicular to bottom surface 16, length h2b of second leg portion 32b may be longer than a sum of length h1b of first leg portion 31b and length h1a of the first lead portion.

With this configuration, first electrode 31 and second electrode 32 are arranged on one side surface of magnetic core 10 without being in contact with each other, and the input and output terminals of inductor 100 can be concentrated on one side surface of magnetic core 10. This makes it possible to improve the mounting efficiency of inductor 100. In addition, with this configuration, the regions that become first electrode 31 and second electrode 32 can be formed at the same time by die-cutting, for example. This makes it possible to improve the production efficiency of inductor 100.

Moreover, coil portion 20 may be arranged closer to first side surface 11 than to second side surface 12 when viewed from on a side on which top surface 17 is located.

With this configuration, length L2a of second lead portion 32a can be lengthened compared to the case where coil portion 20 is arranged at a middle position between first side surface 11 and second side surface 12. With this, the distance between first side surface 11 and second side surface 12 of magnetic core 10 can be narrowed, and the surface area of bottom surface 16 can be reduced. This makes it possible to improve the mounting efficiency of inductor 100.

Moreover, inductor 100 may further include support conductor 40 including a portion protruding outward from fourth side surface 14.

With this configuration, the orientation of inductor 100 can be stabilized. In addition, when inductor 100 is provided on a printed circuit board, connection reliability to the printed circuit board can be ensured.

Moreover, first electrode 31, second electrode 32, and support conductor 40 may protrude beyond bottom surface 16, to a side opposite to a side on which top surface 17 is located.

With this, for example, other electronic components can be disposed on the side on which bottom surface 16 of inductor 100 is located. This makes it possible to improve the mounting efficiency of inductor 100.

Board module 60 according to the present embodiment includes: inductor 100 described above; electronic component 69 different from inductor 100; and printed circuit board 61. Inductor 100 is provided on printed circuit board 61, and electronic component 69 is disposed between bottom surface 16 of magnetic core 10 of inductor 100 and printed circuit board 61.

As described above, the mounting density of board module 60 can be improved by disposing electronic component 69 between bottom surface 16 of magnetic core 10 of inductor 100 and printed circuit board 61.

A method for manufacturing inductor 100 according to the present embodiment is a method for manufacturing an inductor that includes: magnetic core 10 including a magnetic material; coil portion 20 provided inside magnetic core 10; and first electrode 31 and second electrode 32 that are connected to coil portion 20 and arranged outside magnetic core 10. This method includes: forming die-cut conductor plate 52 including regions that become coil portion 20, first electrode 31, and second electrode 32 by die-cutting metal plate 51; forming magnetic core 10 having a rectangular parallelepiped shape including four side surfaces 11 to 14 and forming coil portion 20 including coil axis Ax intersecting two side surfaces 11 and 12 of magnetic core 10 by covering a portion of die-cut conductor plate 52 with a magnetic material; and forming first electrode 31 and second electrode 32 that protrude from one side surface 13 of other two side surfaces 13 and 14 different from the two side surfaces 11 and 12 by bending portions of die-cut conductor plate 52 that are not covered with the magnetic material and arranged outside magnetic core 10.

Accordingly, by forming coil portion 20 of inductor 100 such that coil axis Ax intersects first side surface 11, the coil surface perpendicular to coil axis Ax can be positioned upright and the surface area of bottom surface 16 of magnetic core 10 can be reduced. With this, inductor 100 that can improve the mounting efficiency can be provided. In addition, since first electrode 31 and second electrode 32 are formed to protrude from one side surface 13, two electrodes are arranged on one side surface of magnetic core 10, and the input and output terminals of inductor 100 can be concentrated on one side surface of magnetic core 10. With this, inductor 100 that can improve the mounting efficiency can be provided.

### Other Embodiments, etc.

Although the inductor, etc. according to the embodiment and variations of the present disclosure have been described above, the present disclosure is not limited to the embodiment and variations. The scope of the present disclosure may encompass embodiments as a result of making, to the embodiment and variations, various modifications that may be conceived by those skilled in the art, and different embodiments achieved by combining one or more structural elements in the embodiment and the variations, as long as the resultant embodiments do not depart from the scope of the present disclosure.

In the above embodiment, an example in which coil portion 20 and electrodes 30 of metal component M are formed by processing one component including the same material, but not the present disclosure is not limited to this example. Coil portion 20 and electrodes 30 may be formed by connecting two components including different components.

In the above embodiment, an example in which each of the lead portions and the leg portions of electrodes 30 are linear, but the present disclosure is not limited to this example. For example, each of the lead portions and the leg portions may have a curved shape. For example, the legs portions may be L-shaped or I-shaped.

In the above embodiment, an example in which magnetic core 10 includes one dust core, but the present disclosure is not limited to this example. Magnetic core 10 may include two split magnetic cores. In other words, inductor 100 may include a magnetic core including two split magnetic cores, coil portion 20 sandwiched between the two split magnetic cores, and first electrode 31 and second electrode 32 connected to coil portion 20.

Moreover, inductor 100 may include the following features. The features of the inductor that has been described based on the embodiment are described below.

### <Technique 1>

An inductor includes:
a magnetic core including a magnetic material;
a coil portion provided inside the magnetic core; and
a first electrode and a second electrode that are arranged outside the magnetic core, in which
the magnetic core has a rectangular parallelepiped shape and includes a bottom surface, a top surface opposite to the bottom surface, a first side surface connecting the bottom surface and the top surface, a second side surface opposite to the first side surface, a third side surface perpendicular to the bottom surface and the top surface and connecting the bottom surface and the top surface, and a fourth side surface opposite to the third side surface,
the coil portion is arranged with a coil axis intersecting the first side surface and includes one end and an other end respectively located at both ends of a conductive path of the coil portion,
the one end and the other end of the coil portion are in contact with the third side surface and are spaced apart from each other on the third side surface,
the first electrode is connected to the one end of the coil portion at the third side surface and is arranged along the third side surface, and
the second electrode is connected to the other end of the coil portion at the third side surface and is arranged along the third side surface.

### <Technique 2>

The inductor according to technique 1, in which
the coil portion has a plate shape, and
a flat surface of the coil portion is perpendicular to the bottom surface.

### <Technique 3>

The inductor according to technique 1 or 2, in which
the other end of the coil portion is arranged closer to the top surface than the one end of the coil portion is, and
as viewed in a direction perpendicular to the third side surface, the first electrode is arranged between the one end of the coil portion and the first side surface, and the second electrode is arranged between the other end of the coil portion and the second side surface.

### <Technique 4>

The inductor according to any one of techniques 1 to 3, in which
the first electrode includes a first lead portion that extends in a direction toward the first side surface from the one end of the coil portion, and a first leg portion that is connected to the first lead portion and extends to at least a same plane as the bottom surface, and
the second electrode includes a second lead portion that extends in a direction toward the second side surface from the other end of the coil portion, and a second leg portion that is connected to the second lead portion and extends to at least a same plane as the bottom surface.

### <Technique 5>

The inductor according to technique 4, in which
in a direction perpendicular to the first side surface, a length of the second lead portion is longer than a length of the first lead portion.

### <Technique 6>

The inductor according to technique 5, in which
in a direction perpendicular to the bottom surface, a length of the second leg portion is longer than a length of the first leg portion.

### <Technique 7>

The inductor according to any one of techniques 4 to 6, in which
each of the first electrode and the second electrode has a plate shape,
the first leg portion is connected to a face of the first lead portion that is closer to the bottom surface,
the second leg portion is connected to a face of the second lead portion that is closer to the bottom surface,
in a direction perpendicular to the first side surface, a length obtained by subtracting a length of the second leg portion from a length of the second lead portion is longer than a length of the first lead portion,
in a direction perpendicular to the bottom surface, the length of the second leg portion is longer than a sum of a length of the first leg portion and the length of the first lead portion.

### <Technique 8>

The inductor according to any one of techniques 1 to 7, in which
the coil portion is arranged closer to the first side surface than to the second side surface when viewed from a side on which the top surface is located.

### <Technique 9>

The inductor according to any one of techniques 1 to 8, further includes:
a support conductor including a portion protruding outward from the fourth side surface.

### <Technique 10>

The inductor according to technique 9, in which
the first electrode, the second electrode, and the support conductor protrude beyond the bottom surface, to a side opposite to a side on which the top surface is located.

### <Technique 11>

A board module includes:
the inductor according to technique 10;
an electronic component different from the inductor; and
a printed circuit board, in which
the inductor is provided on the printed circuit board, and
the electronic component is disposed between the bottom surface of the magnetic core of the inductor and the printed circuit board.

### <Technique 12>

A method for manufacturing an inductor that includes: a magnetic core including a magnetic material; a coil portion provided inside the magnetic core; and a first electrode and a second electrode that are connected to the coil portion and arranged outside the magnetic core, the method includes:
forming a die-cut conductor plate including regions that become the coil portion, the first electrode, and the second electrode by die-cutting a metal plate;
forming the magnetic core having a rectangular parallelepiped shape and including four side surfaces and forming a coil portion with a coil axis intersecting two side surfaces of the magnetic core by covering a portion of the die-cut conductor plate with a magnetic material; and
forming the first electrode and the second electrode that protrude from one side surface of other two side surfaces different from the two side surfaces by bending portions of the die-cut conductor plate that are not covered with the magnetic material and arranged outside the magnetic core.

Moreover, the present disclosure also includes, for example, electrical products or circuits including the inductor described above. Electrical products include a power supply device including the inductor described above and various equipment including such a power supply device.

### INDUSTRIAL APPLICABILITY

The inductor according to the present disclosure is useful as inductors to be used in various devices, equipment, etc.

### REFERENCE SIGNS LIST

10 magnetic core
11 first side surface
12 second side surface
13 third side surface
14 fourth side surface
16 bottom surface
17 top surface
20 coil portion
20a one end
20b other end
20f flat surface
21 coil main body
22a, 22b coil lead portion
30 electrode
31 first electrode
31a first lead portion
31b first leg portion
32 second electrode
32a second lead portion
32b second leg portion
40 support conductor
40a support lead portion
40b support leg portion
40c embedded portion
40c2 another end
51 metal plate
52 die-cut conductor plate
52a recess
60 board module
61 printed circuit board
61a mounting surface
63, 64 wire
65, 66, 67 land electrode
69 electronic component
100, 100A, 100B inductor
Ax coil axis
h1a, h1b, h2b, L1a, L2a, L2b length
M metal component

1. An inductor comprising:
a magnetic core including a magnetic material;
a coil portion provided inside the magnetic core; and
a first electrode and a second electrode that are arranged outside the magnetic core, wherein
the magnetic core has a rectangular parallelepiped shape and includes a bottom surface, a top surface opposite to the bottom surface, a first side surface connecting the bottom surface and the top surface, a second side surface opposite to the first side surface, a third side surface perpendicular to the bottom surface and the top surface and connecting the bottom surface and the top surface, and a fourth side surface opposite to the third side surface,
the coil portion is arranged with a coil axis intersecting the first side surface and includes one end and an other end respectively located at both ends of a conductive path of the coil portion,
the one end and the other end of the coil portion are in contact with the third side surface and are spaced apart from each other on the third side surface,
the first electrode is connected to the one end of the coil portion at the third side surface and is arranged along the third side surface, and
the second electrode is connected to the other end of the coil portion at the third side surface and is arranged along the third side surface.

2. The inductor according to claim 1, wherein
the coil portion has a plate shape, and
a flat surface of the coil portion is perpendicular to the bottom surface.

3. The inductor according to claim 1, wherein
the other end of the coil portion is arranged closer to the top surface than the one end of the coil portion is, and
as viewed in a direction perpendicular to the third side surface, the first electrode is arranged between the one end of the coil portion and the first side surface, and the second electrode is arranged between the other end of the coil portion and the second side surface.

4. The inductor according to claim 3, wherein
the first electrode includes a first lead portion that extends in a direction toward the first side surface from the one end of the coil portion, and a first leg portion that is connected to the first lead portion and extends to at least a same plane as the bottom surface, and
the second electrode includes a second lead portion that extends in a direction toward the second side surface from the other end of the coil portion, and a second leg portion that is connected to the second lead portion and extends to at least a same plane as the bottom surface.

5. The inductor according to claim 4, wherein
in a direction perpendicular to the first side surface, a length of the second lead portion is longer than a length of the first lead portion.

6. The inductor according to claim 5, wherein
in a direction perpendicular to the bottom surface, a length of the second leg portion is longer than a length of the first leg portion.

7. The inductor according to claim 4, wherein
each of the first electrode and the second electrode has a plate shape,
the first leg portion is connected to a face of the first lead portion that is closer to the bottom surface,
the second leg portion is connected to a face of the second lead portion that is closer to the bottom surface,
in a direction perpendicular to the first side surface, a length obtained by subtracting a length of the second leg portion from a length of the second lead portion is longer than a length of the first lead portion,
in a direction perpendicular to the bottom surface, the length of the second leg portion is longer than a sum of a length of the first leg portion and the length of the first lead portion.

8. The inductor according to claim 1, wherein
the coil portion is arranged closer to the first side surface than to the second side surface when viewed from a side on which the top surface is located.

9. The inductor according to claim 1, further comprising:
a support conductor including a portion protruding outward from the fourth side surface.

10. The inductor according to claim 9, wherein
the first electrode, the second electrode, and the support conductor protrude beyond the bottom surface, to a side opposite to a side on which the top surface is located.

11. A board module comprising:
the inductor according to claim 10;
an electronic component different from the inductor; and
a printed circuit board, wherein
the inductor is provided on the printed circuit board, and
the electronic component is disposed between the bottom surface of the magnetic core of the inductor and the printed circuit board.

12. A method for manufacturing an inductor that includes: a magnetic core including a magnetic material; a coil portion provided inside the magnetic core; and a first electrode and a second electrode that are connected to the coil portion and arranged outside the magnetic core, the method comprising:
forming a die-cut conductor plate including regions that become the coil portion, the first electrode, and the second electrode by die-cutting a metal plate;
forming the magnetic core having a rectangular parallelepiped shape and including four side surfaces and forming a coil portion with a coil axis intersecting two side surfaces of the magnetic core by covering a portion of the die-cut conductor plate with a magnetic material; and
forming the first electrode and the second electrode that protrude from one side surface of other two side surfaces different from the two side surfaces by bending portions of the die-cut conductor plate that are not covered with the magnetic material and arranged outside the magnetic core.
